(19) United States
(12) Patent Application Publication
(10) Pub. No.: US 2025/0372146 A1
(43) Pub. Date: Dec. 4, 2025

(54) SENSE AMPLIFIER RETENTION IMPROVEMENT

(71) Applicant: Micron Technology, Inc., Boise, ID (US)

(72) Inventor: Daniele Vimercati, El Dorado Hills, CA (US)

(21) Appl. No.: 19/207,142

(22) Filed: May 13, 2025

Related U.S. Application Data
(60) Provisional application No. 63/653,040, filed on May 29, 2024.

(51) Int. Cl. G11C 11/4074; G11C 11/4076; G11C 11/4096

(52) U.S. Cl. CPC G11C 11/4074; G11C 11/4076; G11C 11/4096

(57) ABSTRACT

Systems and methods for sense amplifier power reduction are disclosed including controlling a supply voltage to a sense amplifier through different periods of operation, including providing a first supply voltage to the sense amplifier during an activation period and a second supply voltage to the sense amplifier lower than the first supply voltage during a precharge period to reduce power consumption of the sense amplifier. A voltage supply to a memory cell can be limited to the second supply during the precharge period to reduce a potential voltage stored at the memory cell, increasing memory cell retention.

### PRIORITY APPLICATION

This application claims the benefit of priority to U.S. Provisional Application Ser. No. 63/653,040, filed May 29, 2024, which is incorporated herein by reference in its entirety.

### BACKGROUND

Semiconductor memory technology, particularly Dynamic Random Access Memory (DRAM), has continually evolved to meet increasing demands for faster, more efficient, and higher capacity memory systems. Traditional DRAM architectures face significant challenges in maintaining data integrity over extended periods due to the inherent leakage properties of the capacitors (memory cells) used to store data. Leakage leads to a decay of stored charge, necessitating frequent refresh operations to maintain the stored data, which in turn increases power consumption and reduces the overall efficiency of the memory system. There is a continuous need for retention improvements in semiconductor memory technology.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIGS. 1 and 2 illustrate example relationships between voltage, capacitance, and leakage current of a memory cell.

FIGS. 3A-3C illustrate an example of a sense amplifier in different operating conditions.

FIGS. 4A-4B and 5A-5B illustrate example margin for different sense amplifiers and memory cells at different values of memory cell voltage.

FIGS. 6A-6B illustrates example timing diagrams of different voltage levels in a memory circuit during different modes of DRAM operation.

FIG. 7 illustrates an example method for reducing power consumption of a sense amplifier and, in certain examples, increasing sense amplifier or memory cell retention.

FIG. 8 illustrates an example system including different host and storage devices.

FIG. 9 illustrates an example block diagram of a memory device.

FIG. 10 illustrates a block diagram of an example machine upon which any one or more of the techniques discussed herein may perform.

### DETAILED DESCRIPTION

The present inventors have recognized, among other things, semiconductor memory technology improvements to increase a retention time of a memory cell by one or both of reducing voltage across the memory cell and increasing memory cell capacitance. In an example, reducing the voltage across the memory cell can enable a higher cell capacitance by reducing a required oxide thickness of the memory cell. In addition, reducing the voltage across the memory cell can reduce leakage from the memory cell. The voltage across the memory cell can be reduced by reducing a supply voltage of a sense amplifier, by reducing a voltage on a data line (digit line or bit line (BL)) during a memory operation (e.g., a write operation, etc.), or combinations thereof. One or both of a reduction in voltage and increase in memory cell capacitance (each reducing leakage) can increase retention time of the memory cell (e.g., by 10 ms, from 48 ms to 58 ms). In further combination with an enhanced sense amplifier (an ad-hoc sense amplifier) described in the commonly assigned Vimercati et al. U.S. Application No. 63/553,036, titled “Enhanced Sense Amplifier Architecture,” the contents of which are incorporated herein by reference in its entirety, retention time can be additionally increased (e.g., by 20 ms, from 48 ms to 68 ms).

Reducing the supply voltage of the sense amplifier or the write voltage on the data line during a memory operation, such as a write operation after a read operation of a DRAM memory (e.g., from 1V to 690 mV, etc.) can reduce leakage current through the memory cell, which when combined with a higher cell capacitance, can reduce charge loss of the memory cell, resulting in an increase in retention time of the memory cell and power reduction associated with the reduced supply voltage and increased retention time.

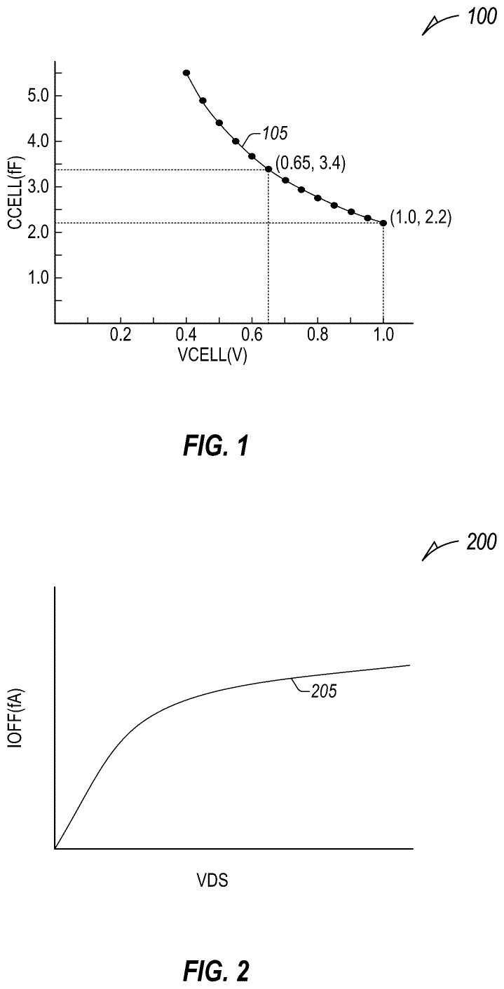

FIGS. 1 and 2 illustrate example relationships between voltage, capacitance, and leakage current of a memory cell. The charge (Q) stored in a memory cell is proportional to the voltage (V) across the capacitor and the capacitance (C) of the memory cell (Q=CV).

FIG. 1 illustrates a relationship 100 between memory cell capacitance (CCELL) in femtofarads (fF) and memory cell voltage (VCELL) in volts (V) for a respective amount of charge (Q) stored in the memory cell. A higher memory cell voltage (VCELL) requires thicker oxide, reducing memory cell capacitance (CCELL) by increasing the distance between the plates of the memory cell for the thicker oxide. Reducing the memory cell voltage (VCELL) enables a higher memory cell capacitance (CCELL) by reducing the required oxide thickness of the memory cell. For example, the charge (Q) stored at a memory cell voltage (VCELL) of 1.0V (1000 mV) and memory cell capacitance (CCELL) of 2.2 fF is roughly equivalent to the charge (Q) stored at a memory cell voltage (VCELL) of 0.65V (650 mV) and memory cell capacitance (CCELL) of 3.4 fF. However, as will be illustrated in FIG. 2, retention of charge in the 3.4 fF example will be greater due to, among other things, a lower leakage current at the reduced voltage.

FIG. 2 illustrates a relationship 200 between leakage current of a transistor (IOFF) in femtoampere (fA) with respect to a drain-to-source voltage (VDS) of the transistor. Reducing a supply voltage of the system (e.g., from 1V to 690 mV, etc.) can reduce leakage current through the transistor, enable higher memory cell capacitance (by reducing required oxide thickness), and reduce charge loss of the memory cell due to leakage, which can result in an increase in retention time of the memory cell and power reduction associated with the reduced supply voltage and increased retention time.

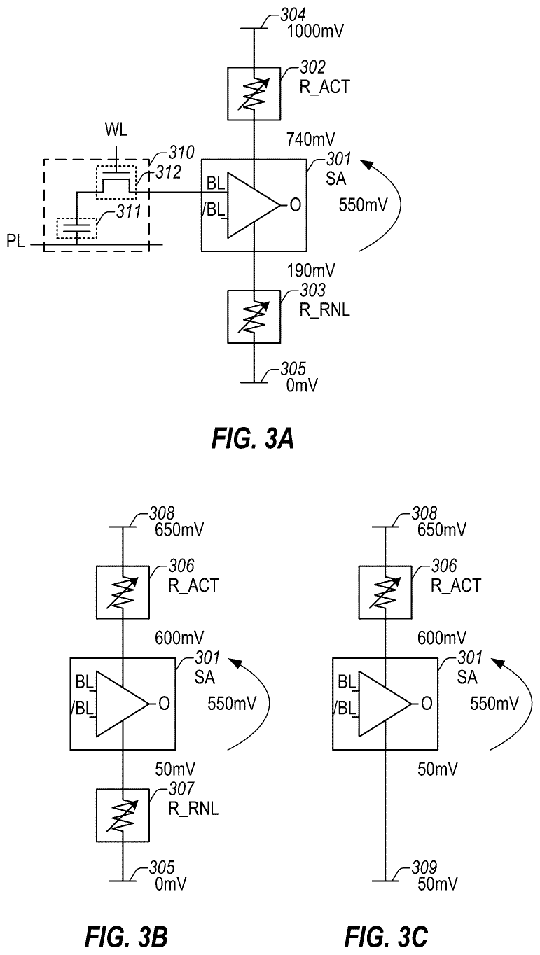

FIGS. 3A-3C illustrate an example of a sense amplifier (SA) 301 in different operating conditions. The sense amplifier 301 includes first and second inputs, for example, to receive complementary bit lines (B1 and/B1) including a bitline (BL) coupled to a memory cell 310 (comprising a selector 312 (e.g., a GAA or other transistor, latch, etc.) and a capacitance 310) and a reference bitline (/BL).

In operation, before reading the value of the memory cell 310, the bitline is precharged to an intermediate voltage, typically half of the supply voltage or the voltage across the sense amplifier 301. When a wordline (WL) for the memory cell 310 is activated, a charge stored by the memory cell 310 either slightly increases or decreases the precharged bitline voltage depending on the stored value of the memory cell 310 (or whether the storage element (e.g., a storage capacitor 311) holds a charge (representing a value “1”) or not (representing a value “0”)). In an example, the storage capacitor 311 can be coupled to a plate line (PL), such as a common plate line between two memory cells (e.g., a pair of memory cells, such as the memory cell coupled to BL and a memory cell coupled to/BL, etc.).

The sense amplifier 301 can detect the change in bitline voltage by comparing the active bitline (BL) against the reference bitline (/BL) and amplifying the difference, providing a logic level “1” or a logic level “0” at an outputs (O) indicative of the value of the memory cell 310. After reading the value of the memory cell 310, the sense amplifier 301 writes back (e.g., refreshes) the value of the memory cell 310 (e.g., restores the charge on the storage capacitor 311), then deactivates the wordline for the memory cell 310, and precharges the bit lines to prepare for subsequent memory cell operations.

Although described above with respect to DRAM architecture and operation, other architectures and operations are contemplated herein. In certain examples, the sense amplifier 301 can include that described in one or more of the commonly assigned: Vimercati et al. U.S. Application No. 63/553,036, titled “Enhanced Sense Amplifier Architecture,” filed on Feb. 13, 2024; Carman et al. U.S. application Ser. No. 18/217,205, titled “Sense Amplifier with Digit Line Multiplexing,” filed on Jun. 30, 2023; Vo et al. U.S. Pat. No. 11,967,362, titled “Pre-Sense Gut Node Amplification in Sense Amplifier,” filed on Jun. 1, 2022; Ingalls et al. U.S. Pat. No. 10,672,435, titled “Sense Amplifier Signal Boost,” filed on Jan. 24, 2019; or McElroy et al. U.S. Pat. No. 9,633,714, titled “Methods for Bias Sensing in DRAM Sense Amplifiers through Voltage-Coupling/Decoupling Devices,” filed on Jun. 26, 2014, the contents of each of which are incorporated herein by reference in their entireties.

In FIG. 3A, the sense amplifier 301 is coupled between a first supply voltage 304 (e.g., a logic high array voltage (VARY), 1000 mV in FIG. 3A, etc.) through a first supply circuit (R_ACT) 302 (e.g., a P type transistor, etc.) and a second supply voltage 305 (e.g., 0 mV, etc.) through a second supply circuit (R_RNL) 303 (e.g., an N type transistor, etc.). In an example, the first supply circuit (R_ACT) 302 can include a P-type latch or driver circuit, and the second circuit (R_RNL) 303 can include an N-type latch or driver circuit (where “RNL” is for Row Nsense Latch). The first and second supply circuits 302, 303 can provide one or more different voltage levels to respective high and low common nodes of the sense amplifier 301 (e.g., 740 mV and 190 mV respectively in FIG. 3A, providing 550 mV across the sense amplifier 301).

In FIGS. 3B-3C, the sense amplifier 301 (and memory cell 310, not illustrated) can be the same as in FIG. 3A. In FIG. 3B, the sense amplifier 301 is coupled between a third supply voltage 308 (e.g., 650 mV) through a third supply circuit (R_ACT) 306 and the second supply voltage 305 (e.g., 0 mV) through a fourth supply circuit (R_RNL) 307. A reduction in supply voltage, such as from 1000 mV to 650 mV, can shift all voltages lower while maintaining the voltage differential across the sense amplifier 301 (e.g., 550 mV, the same as in FIG. 3A), providing power savings without altering circuitry or design of the sense amplifier 301. In addition, a reduction in voltage at the memory cell 310 (e.g., from 1000 mV to 650 mV) enables an increase in capacitance of the memory cell 310 commensurate with the relationship illustrated in FIG. 1 (e.g., an increase in storage capacitance of 2.2 fF to 3.4 fF), reducing leakage commensurate with the relationship illustrated in FIG. 2. The third and fourth supply circuits 306, 307 can provide different voltage levels to respective high and low common nodes of the sense amplifier 301 (e.g., 600 mV and 50 mV respectively in FIG. 3B, providing 550 mV across the sense amplifier 301).

In FIG. 3C, the third supply voltage 308 from FIG. 3B is maintained while the second supply voltage 305 from FIG. 3B is raised (e.g., from 0 mV) to a fourth supply voltage 309 (e.g., 50 mV) and the fourth supply circuit 307 from FIG. 3B is omitted, maintaining the voltage levels to the sense amplifier 301 from FIG. 3B with fewer components.

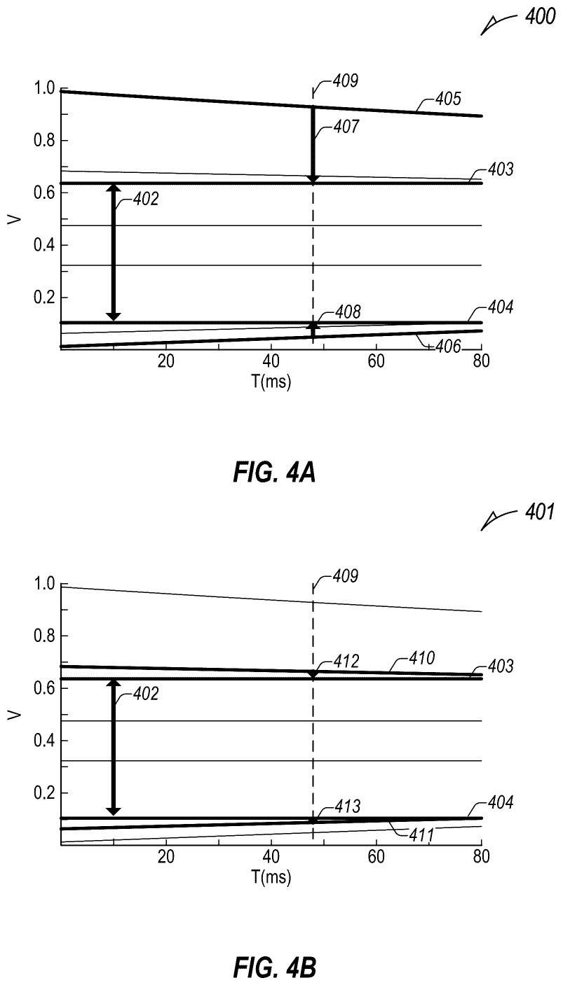

FIGS. 4A-4B illustrate example high and low margins 407, 408 and 412, 413 at a target retention time 409 for a sense amplifier having an error of +5 sigma (c) represented by a dead band 402 having a high threshold 403 at 0.638V (638 mV) and a low threshold 403 at 0.1V (100 mV) and a memory cell having an error of 3.30 represented by a high (value “1”) memory cell value 405 and a low (value “0”) memory cell value 406 over time (e.g., due to leakage, etc.) at different first and second high and low initial values of memory cell voltage (VCELL) of 1.0V (1000 mV) and 0V (0 mV) in FIG. 4A and of 6.9V (690 mV) and 0.05V (50 mV) in FIG. 4B.

The sigma value, representing standard deviation, quantifies the variation or dispersion of performance across a product or process. A sigma value of +5 for the sense amplifier is relatively high, representing a worst-case scenario. A sigma value of 3.3 for the memory cell (e.g., a GAA transistor, a capacitor, etc.) is relatively normal. Two components with different sigma values can be combined into an aggregate as the square root of the sum of the squared sigma values of the individual components. Thus, the combination satisfies a “six sigma” statistical measure.

FIG. 4A illustrates an example relationship 400 between sense amplifier error, represented by the dead band 402, and high and low memory cell value 405, 406 over time at an initial memory cell voltage (VCELL) having a high value at 1.0V (1000 mV) and a low value of 0V (0 mV) (with a storage capacitance of 2.2 fF). The high margin 407 represents the difference between the high memory cell value 405 and the high threshold 403 at the target retention time 409 of 48 ms. The low margin 408 represents the difference between the low memory cell value 406 and the low threshold 404 at the target retention time 409 of 48 ms. Memory cell values outside of the dead band 402 at the target retention time 409 indicate an acceptable combination. In the example illustrated in FIG. 4A, a theoretical maximum retention time well exceeds 80 ms.

FIG. 4B illustrates an example relationship 401 between sense amplifier error, represented by the dead band 402, and high and low memory cell value 410, 411 over time at an initial memory cell voltage (VCELL) having a high value at 0.69V (690 mV) and a low value of 0.05V (50 mV) (with a storage capacitance of 3.45 fF). The high margin 412 represents the difference between the high memory cell value 410 and the high threshold 403 at the target retention time 409 of 48 ms. The low margin 413 represents the difference between the low memory cell value 413 and the low threshold 404 at the target retention time 409 of 48 ms. Memory cell values outside of the dead band 402 at the target retention time 409 indicate an acceptable combination. In the example illustrated in FIG. 4B, a theoretical maximum retention time approaches (or exceeds) 80 ms. In addition, although voltage stored on the memory cell to retain a high value is reduced (e.g., from 1.0V to 0.69V), this isn't so with respect to the low value. However, in operation, both high and low values can be stored, such that the potential voltage stored at the memory cell (the potential high value) is reduced.

FIGS. 5A-5B illustrate example high and low margins 510, 511 at a target retention time 507 for a sense amplifier having an error of Oo represented by a dead band 502 having a high threshold 503 at 0.481V (481 mV) and a low threshold 503 at 0.315V (315 mV) and a memory cell having an error of 60 represented by a high (value “1”) memory cell value 505 and a low (value “0”) memory cell value 506 over time (e.g., due to leakage, etc.) at different first and second high and low initial values of memory cell voltage (VCELL) of 1.0V (1000 mV) and 0V (0 mV) in FIG. 5A and of 6.9V (690 mV) and 0.05V (50 mV) in FIG. 5B. A sigma value of 6 is relatively high, representing a worst-case scenario, whereas a sigma value of 0 is relatively low. However, the two components together combine to satisfy a “six sigma” statistical measure.

FIG. 5A illustrates an example relationship 500 between sense amplifier error, represented by the dead band 502, and high and low memory cell value 505, 506 over time at an initial memory cell voltage (VCELL) having a high value at 1.0V (1000 mV) and a low value of 0V (0 mV) (with a storage capacitance of 2.2 fF). In this example, there is no margin at the target retention time 507 of 48 ms. Thus, the theoretical maximum retention time does not exceed the target retention time 507.

FIG. 5B illustrates an example relationship 501 between sense amplifier error, represented by the dead band 502, and high and low memory cell value 508, 509 over time at an initial memory cell voltage (VCELL) having a high value at 6.9V (690 mV) and a low value of 0.05V (50 mV) (with a storage capacitance of 3.45 fF). The high margin 510 represents the difference between the high memory cell value 508 and the high threshold 503 at the target retention time 507 of 48 ms. The low margin 511 represents the difference between the low memory cell value 509 and the low threshold 504 at the target retention time 507 of 48 ms. Memory cell values outside of the dead band 502 at the target retention time 507 indicate an acceptable combination. In the example illustrated in FIG. 5B, a theoretical maximum retention time approaches (or exceeds) 58 ms, roughly exceeding the target retention time 507 by +10 ms.

In an example, in further combination with the enhanced sense amplifier (the ad-hoc sense amplifier) described in the commonly assigned Vimercati et al. U.S. Application No. 63/553,036, titled “Enhanced Sense Amplifier Architecture,” the contents of which are incorporated herein by reference in its entirety, enhanced sense amplifier improvements can provide additional retention time (e.g., by 20 ms, from 48 ms to 68 ms), such as by enabling an even lower VCELL, such as to 0.55V (550 mV), enabling an additional increase in capacitance to 4.1 fF.

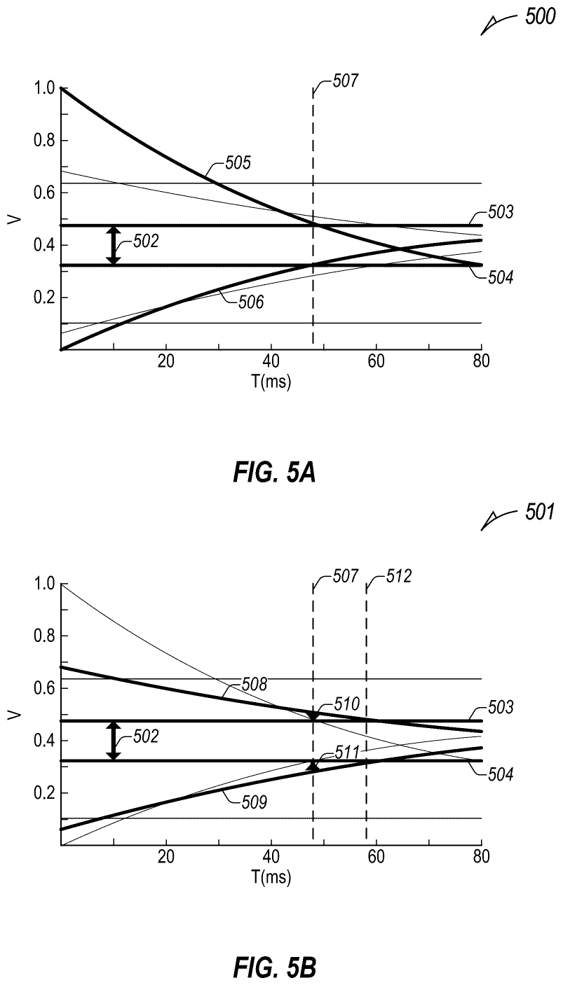

FIGS. 6A-6B illustrates example timing diagrams 600, 601 of different voltage levels in a memory circuit during different modes of DRAM operation. For example, a control circuit (e.g., a memory control unit, a memory controller, etc.) can provide the following DRAM commands: an activation command (e.g., sensing or access); a read/write command; and a precharge command. The above commands are illustrated in the timing diagram 600, 601 as the following periods: an activation period 602 (ACT); a read/write period 603 (R/W); and a precharge period 604 (PRE).

During the activation period 602, after the relevant bit lines are precharged, the word line (WL) is driven high to connect the memory cell to the local digit line (LDL), causing charge transfer to/from the selected memory cells, and the sense amplifier to amplify detected deviation as read data. During the read/write period 603, data can be transferred to a buffer, and the sense amplifier either restores (writes back, refreshes, etc.) the original stored charge to the memory cell or writes back one or more other values, depending on the memory operation. During the precharge period 603, the word line (WL) is driven low to disconnect the memory cell from the bit lines, the buffers are cleared, and the bit lines are precharged to prepare the memory array for subsequent memory cell operations.

The present inventors have recognized, among other things, that the sense amplifier power supply can be reduced during one or more periods or operations, such as during the precharge period 604. In other examples, the sense amplifier power supply can be reduced during both of the read/write and precharge periods 603, 604. In other examples, the sense amplifier power supply can be reduced during all periods of sense amplifier operation. As illustrated in FIGS. 4A-4B and 5A-5B, reducing the sense amplifier power supply can reduce power consumption without altering retention or sense amplifier operation. In other examples, in addition to the reduction in power consumption, reducing the sense amplifier power supply can reduce the write back voltage to the memory cell, increasing sense amplifier or memory cell retention as well as power savings, while additionally enabling an increase in memory cell capacitance, further increasing sense amplifier or memory cell retention without negatively impacting memory cell or sense amplifier performance.

For example, in FIG. 6A, at time T1, during the activation period 602, a local digit line (LDL) (e.g., a data line or a bit line, such as BL in FIG. 3A, etc.) is precharged to a plate line voltage (VPL) 607. At time T2, the word line (WL) 605 is driven high to connect the memory cell to the local digit line, which separates, at time T3, into a high local digit line 608 and a low local digit line 609 depending on the value stored at the memory cell and whether stored charge sinks or sources charge to the local digit line. At time T4, the sense amplifier is connected to the local digit line. The sense amplifier determines and outputs (e.g., at a gut node between the sense amplifier and the memory cell) a high value at 610, commensurate with an array voltage 606 or low value at 611 commensurate with a low voltage 612 (e.g., 0V, etc.), representative of the stored value of the memory cell based on a comparison of the value of the local digit line (e.g., BL) and a reference (e.g., /BL). At time T5, the sense amplifier is driven at different levels to couple and decouple the sense amplifier from the bit line, and charge is transferred between the memory cell and the local digit line, for example, to write back (e.g., refresh) the original value or to provide a new value at the memory cell. At time T6, the array voltage 606 is reduced (lower than before time T6), for example, from 1.0V (1000 mV) in the activation and read/write periods 602, 603 to 0.65V (650 mV) for the precharge period 604, reducing power consumption of the sense amplifier, such as in contrast to the activation and read/write periods 602, 603.

FIG. 6B illustrates an additional shift 613 in the array voltage 606 for the read/write period 603 from 1.0V (1000 mV) to 0.65V (650 mV) and a commensurate reduction in a high value 613 in contrast to the high value 610 from FIG. 6A for additional power savings and retention.

In other examples, although not illustrated in FIGS. 6A-6B, the array voltage 606 can be reduced (e.g., from 1.0V (1000 mV) to 0.65V (650 mV), etc.) for all sense amplifier operation for additional power savings and retention, which additionally enables an increase in capacitance of the memory cell associated therewith, such as illustrated in FIGS. 1, 4B, and 5B, further increasing retention. In addition, in one or more of the examples illustrated above, the low value of the power supply can be increased from 0V to 0.05V (50 mV) or one or more other levels, further reducing the voltage across the memory cell for additional power savings and retention.

Although illustrated above with respect to a read/write operation of a memory cell, such techniques described herein are similarly applicable to one or more other memory operations (e.g., refresh, erase, write, memory management, error correction, etc.).

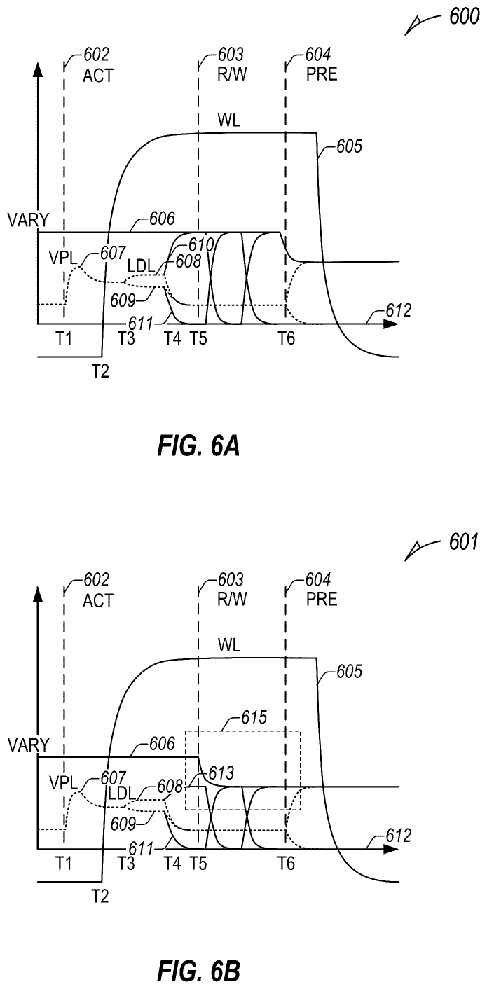

FIG. 7 illustrates an example method 700 for reducing power consumption of a sense amplifier and, in certain examples, increasing sense amplifier or memory cell retention.

At step 701, a supply voltage to a sense amplifier is controlled, such as by a control circuit, such as a memory controller, a memory control unit, a host processor, etc., through different periods of DRAM operation. For example, a sense amplifier can be configured to read a value of a memory cell of a DRAM memory device during an activation period, write back the value of the memory cell during a read/write period, and precharge a bit line of a memory array for a subsequent memory cell operation using a sense amplifier. In an example, the different periods of DRAM operation include the activation period, the read/write period, and the precharge period.

At step 702, a first supply voltage can be provided to the sense amplifier during a first period of operation, such as optionally the activation period illustrated at step 703. In other examples, the first period of operation can include both of the activation period and the read/write period.

At step 704, a second supply voltage can be provided to the sense amplifier lower than the first supply voltage during a second period of operation, such as optionally one or both of the read/write period illustrated at step 705 or the precharge period illustrated at step 706, to reduce power consumption of the sense amplifier.

At step 707, a voltage supply to the memory cell can be controlled using the control circuit, including to limit a voltage to the memory cell to the second supply voltage during the second period to reduce a potential voltage stored at the memory cell, increasing sense amplifier or memory cell retention, such as during the second period. In an example, limiting the voltage to the memory cell to the second supply voltage during the second period can include reducing a voltage of a high “1” value in the memory cell, such as from the first supply voltage to the second supply voltage, increasing sense amplifier or memory cell retention in the second period, such as one or both of the read/write period or the precharge period.

In an example, providing the second supply voltage to the sense amplifier during the second period can include reducing the supply voltage to the sense amplifier during the second period without reducing the voltage differential across the sense amplifier. For example, throughout the different examples illustrated in FIGS. 3A-3C, even though the value of the different supply voltages (high and low) changes, the voltage across the sense amplifier 301 remains 550 mV.

Further, the activation period can include a time of an activation command from the control circuit, such as a time of the activation command from the control circuit to the sense amplifier and subsequent sense amplifier and other memory device actions associated with the activation command. Similarly, the read/write period can include a time of a read/write command from the control circuit and subsequent sense amplifier and other memory device actions associated with the read/write command, and the precharge period can include a time of a precharge command from the control circuit and subsequent sense amplifier and other memory device actions associated with the precharge command.

Although described herein with respect to a specific order of steps, in other examples any one or more of such steps described herein can be omitted or performed in various combinations, subcombinations, or permutations.

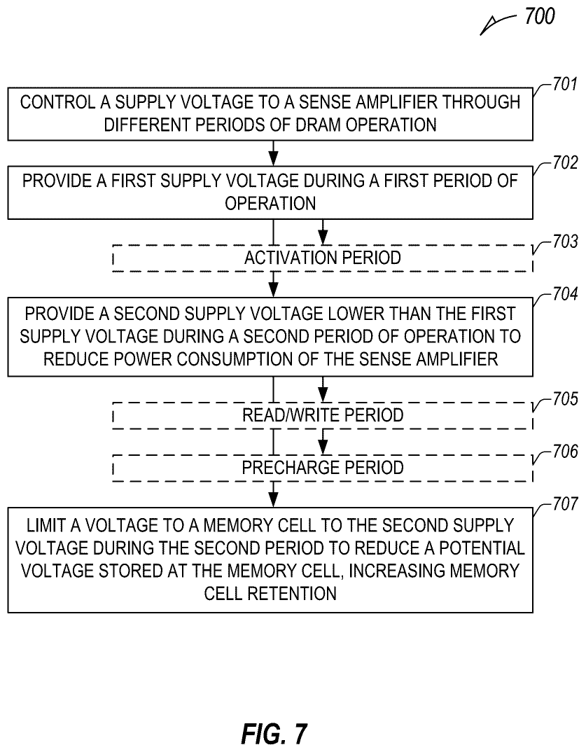

FIG. 8 illustrates an example system 800 (e.g., a host system or processor system) including a host device 805 and a storage device 810 configured to communicate over a communication interface (I/F) 815 (e.g., a bidirectional parallel or serial communication interface). In an example, the communication interface 815 can include a host interface (e.g., an interface from the storage device 810 to the host 805 and vice versa). The communication interface 815 can include a serial or parallel bidirectional interface, such as defined in one or more Joint Electron Device Engineering Council (JEDEC) standards.

The host device 805 can include a host processor 806 (e.g., a host central processing unit (CPU) or other processor or processing circuitry, such as a memory management unit (MMU), interface circuitry, etc.). In certain examples, the host device 805 can include a main memory (MAIN MEM) 808 (e.g., a DRAM memory device, etc.) and optionally, a static memory (STATIC MEM) 809, to support operation of the host processor (HOST PROC) 806.

The storage device 810 can include a non-volatile memory device, in certain examples, a single device separate from the host device 805 and components of the host device 805, in other examples, a component of the host device 805, or in other examples, a combination of separate discrete components. The storage device 810 can include a memory controller (MEM CTRL) 811 and a non-volatile memory device 812. The memory controller 811 can optionally include a limited amount of static memory 819 (or main memory) to support operations of the memory controller 811. In an example, the non-volatile memory device 812 can include a number of non-volatile memory devices (e.g., dies or LUNs), such as one or more stacked flash memory devices (e.g., as illustrated with the stacked dashes underneath the non-volatile memory device 812), etc., each including non-volatile memory (NVM) 813 (e.g., one or more groups of non-volatile memory cells) and a device controller (CTRL) 814 or other periphery circuitry thereon (e.g., device logic, etc.), and controlled by the memory controller 811 over an internal storage-system communication interface (e.g., an Open NAND Flash Interface (ONFI) bus, etc.) separate from the communication interface 815. Control circuitry, as used herein, can refer to one or more of the memory controller 811, the device controller 814, or other periphery circuitry in the storage device 810, the NVM device 812, etc.

The memory controller 811, separate from the host processor 806 and the host device 805, can receive instructions (e.g., computer-executable instructions) from the host device 805, and can communicate with the non-volatile memory device 812, such as to transfer data to (e.g., write or erase) or from (e.g., read) one or more of the memory cells of the non-volatile memory device 812. The memory controller 811 can include, among other things, circuitry or firmware, such as a number of components or integrated circuits, such as one or more memory control units, circuits, or components configured to control access across the memory array and to provide a translation layer between the host device 805 and the storage system 800. The memory manager can include, among other things, circuitry or firmware, such as a number of components or integrated circuits associated with various memory management functions, including, among other functions, wear leveling (e.g., garbage collection or reclamation), error detection or correction, block retirement, or one or more other memory management functions. The memory manager can parse or format host commands (e.g., commands received from the host device 805) into device commands (e.g., commands associated with operation of a memory array, etc.), or generate device commands (e.g., to accomplish various memory management functions) for the device controller 814 or one or more other components of the storage device 810.

In operation, data is typically written to or read from the storage device 810 in pages and erased in blocks. However, one or more memory operations (e.g., read, write, erase, etc.) can be performed on larger or smaller groups of memory cells, as desired. The data transfer size of a memory device is typically referred to as a page, whereas the data transfer size of a host device is typically referred to as a sector. Although a page of data can include a number of bytes of user data (e.g., a data payload including a number of sectors of data) and its corresponding metadata, the size of the page often refers only to the number of bytes used to store the user data. As an example, a page of data having a page size of 4 kB may include 4 kB of user data (e.g., 8 sectors assuming a sector size of 512B) as well as a number of bytes (e.g., 32B, 54B, 224B, etc.) of auxiliary or metadata corresponding to the user data, such as integrity data (e.g., error detecting or correcting code data), address data (e.g., logical address data, etc.), or other metadata associated with the user data.

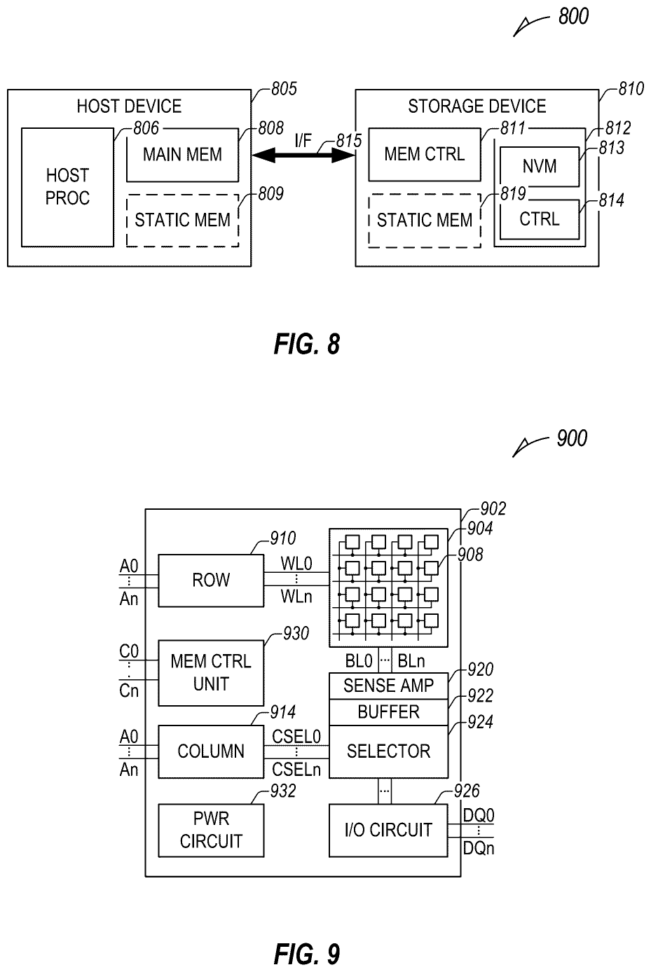

FIG. 9 illustrates an example block diagram 900 of a memory device 902 (e.g., a DRAM memory device) including a memory array 904 (e.g., DRAM memory array) having a plurality of memory cells 908 (e.g., DRAM memory cells) arranged in blocks and sub-blocks and one or more circuits or components to provide communication with, or perform one or more memory operations on, the memory array 904. Although shown with a single memory array 904, in other examples, one or more additional memory arrays, dies, or LUNs can be included herein. In certain examples, in a storage system having a number of dies or LUNs, the memory device 902 can represent a block diagram of circuits and components for each die or LUN. The memory device 902 can include a row decoder 910, a column decoder 914, sense amplifiers 920, a page buffer 922, a selector 924 (e.g., a select circuit), an input/output (I/O) circuit 926, a memory control unit 930, and a power circuit 932.

The memory control unit 930 can control memory operations of the memory device 902 according to one or more signals or instructions received on control lines (CO-Cn), including, for example, one or more clock signals or control signals that indicate a desired operation (e.g., write, read, erase, etc.), or address signals (A0-AX) received on one or more address lines. One or more devices external to the memory device 902 can control the values of the control signals on the control lines, or the address signals on the address line 916, including but not limited to a host, a memory controller, a processor, or one or more circuits or components not illustrated in FIG. 9.

The memory device 902 can use access lines (e.g., word lines (WL) WL0-WLn) and data lines (e.g., bit lines (BL) BL0-BLn) to transfer data to (e.g., write or erase) or from (e.g., read) one or more of the memory cells 908. The memory device 902 can include sense circuitry, such as the sense amplifier 920, configured to determine the values of data on (e.g., read), or to determine the values of data to be written to, the memory cells 908 using data lines. For example, the sense amplifier 920 can read a logic level in a selected memory cell in response to a read current flowing in the memory array 904 to the data lines, such as through a selected string comprising the selected memory cell.

The input/output (I/O) circuit 926 can transfer values of data in or out of the memory device 902, such as in or out of the page buffer 922 or the memory array 904, using I/O lines (DQ0-DQn), according to, for example, the control lines and address lines. The page buffer 922 can store data received from the one or more devices external to the memory device 902 before the data is programmed into the memory array 904 or can store data read from the memory array 904 before the data is transmitted to the one or more devices external to the memory device 902.

The column decoder 914 can receive and decode address signals (A0-AX) into one or more column select signals (CSEL0-CSELn). The selector 924 can receive the column select signals and select data in the page buffer 922 representing values of data to be read from or to be programmed into memory cells 908. Selected data can be transferred between the page buffer 922 and the I/O circuit 926 using second data lines.

The state of a selected memory cell can be accessed by sensing a current or voltage variation associated with a particular data line containing the selected memory cell. The memory array 904 can be accessed (e.g., by a control circuit, one or more processors, digital logic, etc.) using one or more drivers. In an example, one or more drivers can activate a specific memory cell, or set of memory cells, by driving a particular potential to one or more data lines (e.g., bit lines BL0-BL2), access lines (e.g., word lines WL0-WL7), or select gates, depending on the type of operation desired to be performed on the specific memory cell or set of memory cells.

To program or write data to a memory cell, a programming voltage (Vpgm) (e.g., one or more programming pulses, etc.) can be applied to selected word lines, and thus, to a control gate of each memory cell coupled to the selected word lines. Programming pulses can begin, for example, at or near 15V, and, in certain examples, can increase in magnitude during each programming pulse application. While the program voltage is applied to the selected word lines, a potential, such as a ground potential (e.g., Vss), can be applied to the data lines (e.g., bit lines) and substrates (and thus the channels, between the sources and drains) of the memory cells targeted for programming, resulting in a charge transfer from the channels to the targeted memory cells.

In contrast, a pass voltage (Vpass) can be applied to one or more word lines having memory cells that are not targeted for programming, or an inhibit voltage (e.g., Vcc) can be applied to data lines (e.g., bit lines) having memory cells that are not targeted for programming, for example, to inhibit charge from being transferred from the channels to the floating gates of such non-targeted memory cells. The pass voltage can be variable, depending, for example, on the proximity of the applied pass voltages to a word line targeted for programming. The inhibit voltage can include a supply voltage (Vcc), such as a voltage from an external source or supply (e.g., a battery, an AC-to-DC converter, etc.), relative to a ground potential (e.g., Vss).

As an example, if a programming voltage (e.g., 15V or more) is applied to a specific word line, a pass voltage of 10V can be applied to one or more other word lines to inhibit programming of non-targeted memory cells, or to retain the values stored on such memory cells not targeted for programming. In addition, sense amplifiers can be coupled to one or more of the data lines (e.g., bit lines BL0-BLn) and can detect the state of a memory cell in a respective data line by sensing a voltage or current on the particular data line.

In an example, the memory control unit 930 can control one or more power or voltage levels described herein of the memory device 902, the sense amplifier 920, or the memory array 904, such as using one or more power levels (e.g., supply voltages) received or provided by the power circuit 932 or controlling one or more latches or transistors to couple or decouple one or more supply voltages or power levels associated therewith.

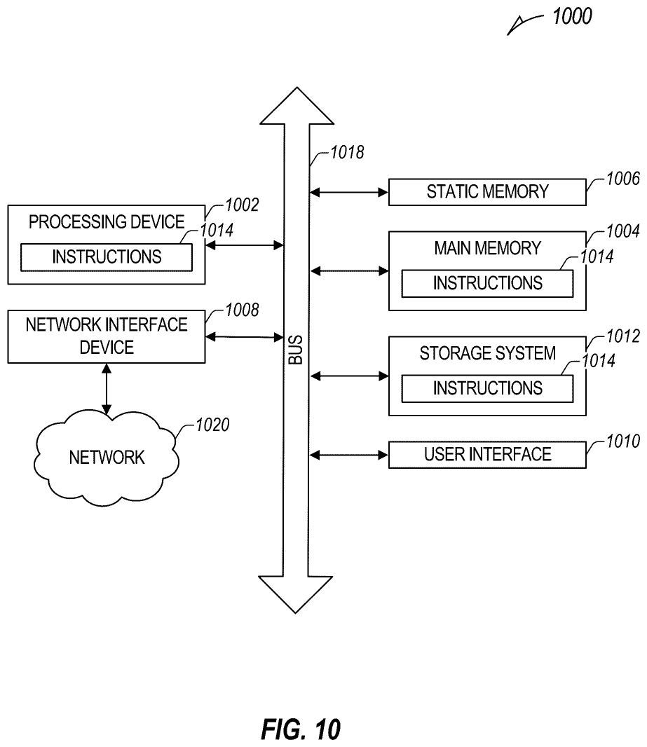

FIG. 10 illustrates a block diagram of an example machine 1000 (e.g., a host system, a user device, a server, etc.) upon which any one or more of the techniques (e.g., methodologies) discussed herein may perform. In alternative embodiments, the machine 1000 may operate as a standalone device or may be connected (e.g., networked) to other machines. In a networked deployment, the machine 1000 may operate in the capacity of a server machine, a client machine, or both in server-client network environments. In an example, the machine 1000 may function as a peer machine in peer-to-peer (P2P) (or other distributed) network environment. The machine 1000 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine 1000 (e.g., computer system, a host system, etc.) may include a processing device 1002 (e.g., a hardware processor, a central processing unit (CPU), a graphics processing unit (GPU), a hardware processor core, or any combination thereof, etc.), a main memory 1004 (e.g., read-only memory (ROM), dynamic random-access memory (DRAM), a static memory 1006 (e.g., static random-access memory (SRAM), etc.), and a storage system 1012, some or all of which may communicate with each other via a communication interface 1018 (e.g., a bus).

The processing device 1002 can represent one or more general-purpose processing devices such as a microprocessor, a central processing unit, etc. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 1002 can also be one or more special-purpose processing devices such as an application specific integrated circuit (ASIC), a field programmable gate array (FPGA), a digital signal processor (DSP), network processor, etc. The processing device 1002 can be configured to execute instructions 1014 for performing the operations and steps discussed herein. The machine 1000 can further include a network interface device 1008 to communicate over a network 1020.

The storage system 1012 can include a machine-readable storage medium (also known as a computer-readable medium) on which is stored one or more sets of instructions 1014 or software embodying any one or more of the methodologies or functions described herein. The instructions 1014 can also reside, completely or at least partially, within the main memory 1004 or within the processing device 1002 during execution thereof by the machine 1000, the main memory 1004 and the processing device 1002 also constituting machine-readable storage media.

The term “machine-readable storage medium” should be taken to include a single medium or multiple media that store the one or more sets of instructions, or any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media. In an example, a massed machine-readable medium comprises a machine-readable medium with a plurality of particles having invariant (e.g., rest) mass. Accordingly, massed machine-readable media are not transitory propagating signals. Specific examples of massed machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The machine 1000 may further include a user interface 1010, such as one or more of a display unit, an alphanumeric input device (e.g., a keyboard), and a user interface (UI) navigation device (e.g., a mouse), etc. In an example, one or more of the display unit, the input device, or the UI navigation device may be a touch screen display. The machine a signal generation device (e.g., a speaker), or one or more sensors, such as a global positioning system (GPS) sensor, compass, accelerometer, or one or more other sensor. The machine 1000 may include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The instructions 1014 (e.g., software, programs, an operating system (OS), etc.) or other data are stored on the storage system 1012 can be accessed by the main memory 1004 for use by the processing device 1002. The main memory 1004 (e.g., DRAM) is typically fast, but volatile, and thus a different type of storage than the storage system 1012 (e.g., an SSD), which is suitable for long-term storage, including while in an “off” condition. The instructions 1014 or data in use by a user or the machine 1000 are typically loaded in the main memory 1004 for use by the processing device 1002. When the main memory 1004 is full, virtual space from the storage system 1012 can be allocated to supplement the main memory 1004; however, because the storage system 1012 device is typically slower than the main memory 1004, and write speeds are typically at least twice as slow as read speeds, use of virtual memory can greatly reduce user experience due to storage system latency (in contrast to the main memory 1004, e.g., DRAM). Further, use of the storage system 1012 for virtual memory can greatly reduce the usable lifespan of the storage system 1012.

The instructions 1014 may further be transmitted or received over a network 1020 using a transmission medium via the network interface device 1008 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, the network interface device 1008 may include one or more physical jacks (e.g., Ethernet, coaxial, or phone jacks) or one or more antennas to connect to the network 1020. In an example, the network interface device 1008 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the machine 1000, and includes digital or analog communications signals or other intangible medium to facilitate communication of such software.

The above detailed description includes references to the accompanying drawings, which form a part of the detailed description. The drawings show, by way of illustration, specific embodiments in which the invention can be practiced. These embodiments are also referred to herein as examples. Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In various examples, the components, controllers, processors, units, engines, or tables described herein can include, among other things, physical circuitry or firmware stored on a physical device. As used herein, “processor” means any type of computational circuit such as, but not limited to, a microprocessor, a microcontroller, a graphics processor, a digital signal processor (DSP), or any other type of processor or processing circuit, including a group of processors or multi-core devices.

As used herein, directional adjectives, such as horizontal, vertical, normal, parallel, perpendicular, etc., can refer to relative orientations, and are not intended to require strict adherence to specific geometric properties, unless otherwise noted. It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can be either be coupled, or directly coupled, unless otherwise indicated.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, etc. Such code can include computer readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

Embodiments may be implemented in one or a combination of hardware, firmware, and software. Embodiments may also be implemented as instructions stored on a machine-readable storage device, which may be read and executed by at least one processor to perform the operations described herein. A machine-readable storage device may include any non-transitory mechanism for storing information in a form readable by a machine (e.g., a computer). For example, a machine-readable storage device may include read-only memory (ROM), random-access memory (RAM), magnetic disk storage media, optical storage media, flash-memory devices, and other storage devices and media.

A processor subsystem may be used to execute the instruction on the readable medium. The processor subsystem may include one or more processors, each with one or more cores. Additionally, the processor subsystem may be disposed on one or more physical devices. The processor subsystem may include one or more specialized processors, such as a graphics processing unit (GPU), a digital signal processor (DSP), a field programmable gate array (FPGA), or a fixed function processor.

Examples, as described herein, may include, or may operate on, logic or a number of components, modules, or mechanisms. Modules may be hardware, software, or firmware communicatively coupled to one or more processors in order to carry out the operations described herein. Modules may be hardware modules, and as such modules may be considered tangible entities capable of performing specified operations and may be configured or arranged in a certain manner. In an example, circuits may be arranged (e.g., internally or with respect to external entities such as other circuits) in a specified manner as a module. In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine-readable medium. In an example, the software, when executed by the underlying hardware of the module, causes the hardware to perform the specified operations. Accordingly, the term hardware module is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using software; the general-purpose hardware processor may be configured as respective different modules at different times. Software may accordingly configure a hardware processor, for example, to constitute a particular module at one instance of time and to constitute a different module at a different instance of time. Modules may also be software or firmware modules, which operate to perform the methodologies described herein.

As used in any embodiment herein, the term “logic” may refer to firmware or circuitry configured to perform any of the aforementioned operations. Firmware may be embodied as code, instructions, data hard-coded (e.g., nonvolatile) in memory devices or circuitry, or combinations thereof.

“Circuitry,” as used in any embodiment herein, may comprise, for example, any combination or permutation of hardwired circuitry, programmable circuitry, state machine circuitry, logic, or firmware that stores instructions executed by programmable circuitry. The circuitry may be embodied as an integrated circuit, such as an integrated circuit chip. In some embodiments, the circuitry may be formed, at least in part, by the processor circuitry executing code or instruction sets (e.g., software, firmware, etc.) corresponding to the functionality described herein, thus transforming a general-purpose processor into a specific-purpose processing environment to perform one or more of the operations described herein. In some embodiments, the processor circuitry may be embodied as a stand-alone integrated circuit or may be incorporated as one of several components on an integrated circuit. In some embodiments, the various components and circuitry of the node or other systems may be combined in a system-on-a-chip (SoC) architecture.

Example 1 is a system, comprising: a sense amplifier configured to read a value of a memory cell of a DRAM memory device, write back the value of the memory cell, and precharge a bit line for a subsequent memory cell operation; and a control circuit configured to control a supply voltage to a sense amplifier through different periods of DRAM operation, including an activation period, a read/write period, and a precharge period, wherein the control circuit is configured to provide a first supply voltage to the sense amplifier during the activation period and to provide a second supply voltage to the sense amplifier lower than the first supply voltage during the precharge period to reduce power consumption of the sense amplifier.

In Example 2, the subject matter of Example 1 includes, wherein the control circuit is configured to control a voltage supply to the memory cell, including to limit a voltage to the memory cell to the second supply voltage during the precharge period to reduce a potential voltage stored at the memory cell, increasing sense amplifier or memory cell retention.

In Example 3, the subject matter of Example 2 includes, wherein to limit the voltage to the memory cell to the second supply voltage during the precharge period comprises to reduce a voltage of a high value in the memory cell from the first supply voltage to the second supply voltage, increasing sense amplifier or memory cell retention.

In Example 4, the subject matter of Examples 1-3 includes, wherein the control circuit is configured to provide the second supply voltage to the sense amplifier during the read/write period and the precharge period to reduce power consumption of the sense amplifier.

In Example 5, the subject matter of Example 4 includes, wherein the control circuit is configured to control a voltage supply to the memory cell, including to limit a voltage to the memory cell to the second supply voltage during the read/write period and the precharge period to reduce a potential voltage stored at the memory cell, increasing sense amplifier or memory cell retention.

In Example 6, the subject matter of Example 5 includes, wherein to limit the voltage to the memory cell to the second supply voltage during the read/write period and the precharge period comprises to reduce a voltage of a high value in the memory cell from the first supply voltage to the second supply voltage, increasing sense amplifier or memory cell retention.

In Example 7, the subject matter of Examples 1-6 includes, wherein the control circuit is configured to reduce the supply voltage to the sense amplifier during the precharge period without reducing a voltage differential across the sense amplifier.

In Example 8, the subject matter of Examples 1-7 includes, wherein the activation period comprises a time of an activation command from the control circuit, the read/write period comprises a time of a read/write command from the control circuit, and the precharge period comprises a time of a precharge command from the control circuit.

Example 9 is a method, comprising: reading a value of a memory cell of a DRAM memory device during an activation period, writing back the value of the memory cell during a read/write period, and precharging a bit line of a memory array for a subsequent memory cell operation during a precharge period using a sense amplifier; and controlling a supply voltage to the sense amplifier through different periods of DRAM operation using a control circuit, wherein the different periods of DRAM operation include, the activation period, the read/write period, and the precharge period, and controlling the supply voltage comprises: providing a first supply voltage to the sense amplifier during the activation period; and providing a second supply voltage to the sense amplifier lower than the first supply voltage during the precharge period to reduce power consumption of the sense amplifier.

In Example 10, the subject matter of Example 9 includes, controlling a voltage supply to the memory cell using the control circuit, including limiting a voltage to the memory cell to the second supply voltage during the precharge period to reduce a potential voltage stored at the memory cell, increasing sense amplifier or memory cell retention.

In Example 11, the subject matter of Example 10 includes, wherein limiting the voltage to the memory cell to the second supply voltage during the precharge period comprises reducing a voltage of a high value in the memory cell from the first supply voltage to the second supply voltage, increasing sense amplifier or memory cell retention.

In Example 12, the subject matter of Examples 9-11 includes, providing the second supply voltage to the sense amplifier during the read/write period and the precharge period to reduce power consumption of the sense amplifier.

In Example 13, the subject matter of Example 12 includes, controlling a voltage supply to the memory cell using the control circuit, including limiting a voltage to the memory cell to the second supply voltage during the read/write period and the precharge period to reduce a potential voltage stored at the memory cell, increasing sense amplifier or memory cell retention.

In Example 14, the subject matter of Example 13 includes, wherein limiting the voltage to the memory cell to the second supply voltage during the read/write period and the precharge period comprises reducing a voltage of a high value in the memory cell from the first supply voltage to the second supply voltage, increasing sense amplifier or memory cell retention.

In Example 15, the subject matter of Examples 9-14 includes, wherein providing the second supply voltage to the sense amplifier during the precharge period comprises reducing the supply voltage to the sense amplifier during the precharge period without reducing a voltage differential across the sense amplifier.

In Example 16, the subject matter of Examples 9-15 includes, wherein the activation period comprises a time of an activation command from the control circuit, the read/write period comprises a time of a read/write command from the control circuit, and the precharge period comprises a time of a precharge command from the control circuit.

Example 17 is a system, comprising: one or more processors; and a memory storing computer-executable instructions that, when executed, cause the one or more processors to control the system to perform operations comprising: reading a value of a memory cell during an activation period, writing back the value of the memory cell during a read/write period, and precharging a bit line of a memory array for a subsequent memory cell operation during a precharge period; and controlling a supply voltage to a sense amplifier through different periods of operation, wherein the different periods of operation include, the activation period, the read/write period, and the precharge period, and controlling the supply voltage comprises: providing a first supply voltage to the sense amplifier during the activation period; and providing a second supply voltage to the sense amplifier lower than the first supply voltage during the precharge period to reduce power consumption of the sense amplifier.

In Example 18, the subject matter of Example 17 includes, wherein the operations comprise: controlling a voltage supply to the memory cell, including limiting a voltage to the memory cell to the second supply voltage during the precharge period to reduce a potential voltage stored at the memory cell, increasing sense amplifier or memory cell retention.

In Example 19, the subject matter of Examples 17-18 includes, wherein the operations comprise: providing the second supply voltage to the sense amplifier during the read/write period and the precharge period to reduce power consumption of the sense amplifier.

In Example 20, the subject matter of Example 19 includes, wherein the operations comprise: controlling a voltage supply to the memory cell, including limiting a voltage to the memory cell to the second supply voltage during the read/write period and the precharge period to reduce a potential voltage stored at the memory cell, increasing sense amplifier or memory cell retention.

In Example 21, subject matter (e.g., a system or apparatus) may optionally combine any portion or combination of any portion of any one or more of Examples 1-20 to comprise “means for” performing any portion of any one or more of the functions or methods of Examples 1-20, or at least one “non-transitory machine-readable medium” including instructions that, when performed by a machine, cause the machine to perform any portion of any one or more of the functions or methods of Examples 1-20.

The above detailed description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72 (b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the disclosure should, therefore, be determined with references to the appended claims, along with the full scope of equivalents to which such claims are entitled.

What is claimed is:

1. A system, comprising:
a sense amplifier configured to read a value of a memory cell of a DRAM memory device, write back the value of the memory cell, and precharge a bit line for a subsequent memory cell operation; and
a control circuit configured to control a supply voltage to a sense amplifier through different periods of DRAM operation, including an activation period, a read/write period, and a precharge period,
wherein the control circuit is configured to provide a first supply voltage to the sense amplifier during the activation period and to provide a second supply voltage to the sense amplifier lower than the first supply voltage during the precharge period to reduce power consumption of the sense amplifier.

2. The system of claim 1, wherein the control circuit is configured to control a voltage supply to the memory cell, including to limit a voltage to the memory cell to the second supply voltage during the precharge period to reduce a potential voltage stored at the memory cell, increasing sense amplifier retention.

3. The system of claim 2, wherein to limit the voltage to the memory cell to the second supply voltage during the precharge period comprises to reduce a voltage of a high value in the memory cell from the first supply voltage to the second supply voltage, increasing sense amplifier retention.

4. The system of claim 1, wherein the control circuit is configured to provide the second supply voltage to the sense amplifier during the read/write period and the precharge period to reduce power consumption of the sense amplifier.

5. The system of claim 4, wherein the control circuit is configured to control a voltage supply to the memory cell, including to limit a voltage to the memory cell to the second supply voltage during the read/write period and the precharge period to reduce a potential voltage stored at the memory cell, increasing sense amplifier retention.

6. The system of claim 5, wherein to limit the voltage to the memory cell to the second supply voltage during the read/write period and the precharge period comprises to reduce a voltage of a high value in the memory cell from the first supply voltage to the second supply voltage, increasing sense amplifier retention.

7. The system of claim 1, wherein the control circuit is configured to reduce the supply voltage to the sense amplifier during the precharge period without reducing a voltage differential across the sense amplifier.

8. The system of claim 1, wherein the activation period comprises a time of an activation command from the control circuit, the read/write period comprises a time of a read/write command from the control circuit, and the precharge period comprises a time of a precharge command from the control circuit.

9. A method, comprising:
reading a value of a memory cell of a DRAM memory device during an activation period, writing back the value of the memory cell during a read/write period, and precharging a bit line of a memory array for a subsequent memory cell operation during a precharge period using a sense amplifier; and
controlling a supply voltage to the sense amplifier through different periods of DRAM operation using a control circuit, wherein the different periods of DRAM operation include the activation period, the read/write period, and the precharge period, and controlling the supply voltage comprises:
providing a first supply voltage to the sense amplifier during the activation period; and
providing a second supply voltage to the sense amplifier lower than the first supply voltage during the precharge period to reduce power consumption of the sense amplifier.

10. The method of claim 9, comprising:
controlling a voltage supply to the memory cell using the control circuit, including limiting a voltage to the memory cell to the second supply voltage during the precharge period to reduce a potential voltage stored at the memory cell, increasing sense amplifier retention.

11. The method of claim 10, wherein limiting the voltage to the memory cell to the second supply voltage during the precharge period comprises reducing a voltage of a high value in the memory cell from the first supply voltage to the second supply voltage, increasing sense amplifier retention.

12. The method of claim 9, comprising:
providing the second supply voltage to the sense amplifier during the read/write period and the precharge period to reduce power consumption of the sense amplifier.

13. The method of claim 12, comprising:
controlling a voltage supply to the memory cell using the control circuit, including limiting a voltage to the memory cell to the second supply voltage during the read/write period and the precharge period to reduce a potential voltage stored at the memory cell, increasing sense amplifier retention.

14. The method of claim 13, wherein limiting the voltage to the memory cell to the second supply voltage during the read/write period and the precharge period comprises reducing a voltage of a high value in the memory cell from the first supply voltage to the second supply voltage, increasing sense amplifier retention.

15. The method of claim 9, wherein providing the second supply voltage to the sense amplifier during the precharge period comprises reducing the supply voltage to the sense amplifier during the precharge period without reducing a voltage differential across the sense amplifier.

16. The method of claim 9, wherein the activation period comprises a time of an activation command from the control circuit, the read/write period comprises a time of a read/write command from the control circuit, and the precharge period comprises a time of a precharge command from the control circuit.

17. A system, comprising:
one or more processors; and
a memory storing computer-executable instructions that, when executed, cause the one or more processors to control the system to perform operations comprising:
reading a value of a memory cell during an activation period, writing back the value of the memory cell during a read/write period, and precharging a bit line of a memory array for a subsequent memory cell operation during a precharge period; and
controlling a supply voltage to a sense amplifier through different periods of operation, wherein the different periods of operation include the activation period, the read/write period, and the precharge period, and controlling the supply voltage comprises:
providing a first supply voltage to the sense amplifier during the activation period; and
providing a second supply voltage to the sense amplifier lower than the first supply voltage during the precharge period to reduce power consumption of the sense amplifier.

18. The system of claim 17, wherein the operations comprise:
controlling a voltage supply to the memory cell, including limiting a voltage to the memory cell to the second supply voltage during the precharge period to reduce a potential voltage stored at the memory cell, increasing sense amplifier retention.

19. The system of claim 17, wherein the operations comprise:
providing the second supply voltage to the sense amplifier during the read/write period and the precharge period to reduce power consumption of the sense amplifier.

20. The system of claim 19, wherein the operations comprise:
controlling a voltage supply to the memory cell, including limiting a voltage to the memory cell to the second supply voltage during the read/write period and the precharge period to reduce a potential voltage stored at the memory cell, increasing sense amplifier retention.
